(19) United States
(12) Patent Application Publication
(10) Pub. No.: US 2025/0187335 A1
(43) Pub. Date: Jun. 12, 2025

(54) ACTUATOR, LIQUID EJECTION HEAD, AND PRINTER

(71) Applicant: SEIKO EPSON CORPORATION, Tokyo (JP)

(72) Inventors: Yasuaki HAMADA, CHINO-SHI (JP); Koji OHASHI, MATSUMOTO-SHI (JP); Yoshiki YANO, CHINO-SHI (JP); Kazuya KITADA, MATSUMOTO-SHI (JP); Masao NAKAYAMA, SHIOJIRI-SHI (JP)

(21) Appl. No.: 18/973,694

(22) Filed: Dec. 9, 2024

(30) Foreign Application Priority Data
Dec. 8, 2023 (JP) 2023-207612

(51) Int. Cl. B41J 2/14; H10N 30/853; H10N 30/87

(52) U.S. Cl. CPC B41J 2/14233; H10N 30/8542; H10N 30/8561; H10N 30/877

(57) ABSTRACT

An actuator includes: a vibration plate; a first electrode provided above the vibration plate; a piezoelectric layer that is provided above the first electrode and that contains a composite oxide having a perovskite structure; and a second electrode provided above the piezoelectric layer, in which a residual polarization of the piezoelectric layer is 0.535 times or less a spontaneous polarization of the piezoelectric layer.

The present application is based on, and claims priority from JP Application Serial Number 2023-207612, filed Dec. 8, 2023, the disclosure of which is hereby incorporated by reference herein in its entirety.

### BACKGROUND

### 1. Technical Field

The present disclosure relates to an actuator, a liquid ejection head, and a printer.

### 2. Related Art

An actuator including a vibration plate and a piezoelectric element is applied to, for example, a liquid ejection head of an ink jet printer.

For example, JP-A-2000-294844 describes a piezoelectric actuator including a vibration plate and a piezoelectric element including a piezoelectric thin film having a crystal structure in which directions of spontaneous polarization are aligned in a certain direction.

In the piezoelectric actuator as described above, as a displacement amount of the vibration plate increases, an increment of the displacement amount of the vibration plate with respect to an increment of a displacement amount of the piezoelectric thin film decreases. Therefore, this causes a problem that as a voltage applied to the piezoelectric element increases, the increment of the displacement amount of the vibration plate decreases.

### SUMMARY

An actuator according to an aspect of the present disclosure includes:
a vibration plate;
a first electrode provided above the vibration plate;
a piezoelectric layer that is provided above the first electrode and that contains a composite oxide having a perovskite structure; and
a second electrode provided above the piezoelectric layer, in which
a residual polarization of the piezoelectric layer is 0.535 times or less a spontaneous polarization of the piezoelectric layer.

A liquid ejection head according to an aspect of the present disclosure includes:
the actuator according to the aspect; and
a nozzle plate formed with a nozzle hole, in which
a substrate is provided between the nozzle plate and the vibration plate and is formed with a pressure generation chamber communicating with the nozzle hole.

A printer according to an aspect of the present disclosure includes:
the liquid ejection head;
a conveyance mechanism configured to move a recording medium with respect to the liquid ejection head; and
a control unit configured to control the liquid ejection head and the conveyance mechanism.

### BRIEF DESCRIPTION OF THE DRAWINGS

FIG. 1 is a cross-sectional view schematically illustrating an actuator according to the embodiment.

FIG. 2 illustrates a hysteresis curve of the actuator according to the embodiment.

FIG. 3 is a cross-sectional view schematically illustrating steps of manufacturing the actuator according to the embodiment.

FIG. 4 is a diagram illustrating a tensile stress generated in a piezoelectric layer of the actuator according to the embodiment.

FIG. 5 is an exploded perspective view schematically illustrating a liquid ejection head according to the embodiment.

FIG. 6 is a plan view schematically illustrating the liquid ejection head according to the embodiment.

FIG. 7 is a cross-sectional view schematically illustrating the liquid ejection head according to the embodiment.

FIG. 8 is a perspective view schematically illustrating a printer according to the embodiment.

FIG. 9 illustrates a hysteresis curve of Example 1.

FIG. 10 illustrates a hysteresis curve of Example 2.

FIG. 11 illustrates a hysteresis curve of Comparative Example 1.

FIG. 12 is a graph illustrating a relation between an electric field generated in a piezoelectric layer and a displacement amount of a vibration plate in Examples 1 and 2 and Comparative Example 1.

FIG. 13 is a table illustrating a list of experimental results of Examples 1 and 2 and Comparative Example 1.

### DESCRIPTION OF EMBODIMENTS

Hereinafter, a preferred embodiment according to the present disclosure will be described in detail with reference to the drawings. The embodiment described below do not unreasonably limit the content of the present disclosure set forth in the appended claims. Further, all the configurations to be described below are not necessarily essential elements of the present disclosure.

### 1. Actuator

### 1.1. Configuration

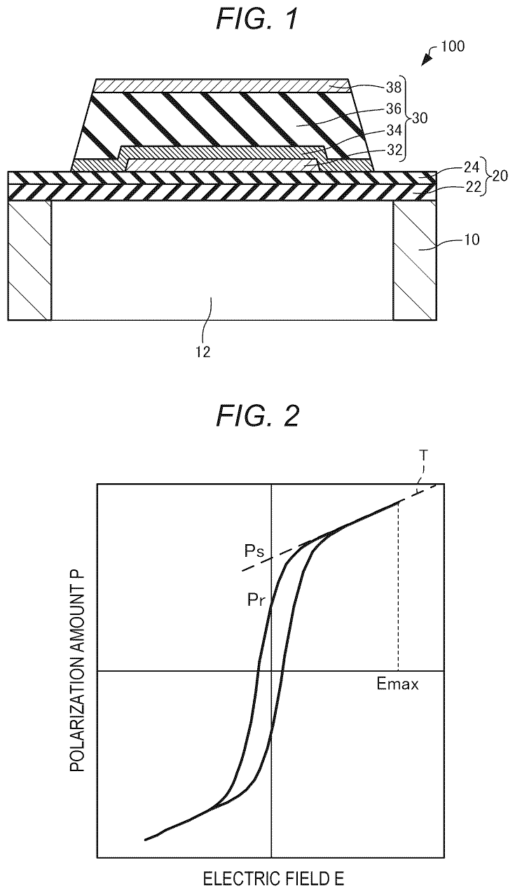

First, an actuator according to the embodiment will be described with reference to the drawings. FIG. 1 is a cross-sectional view schematically illustrating an actuator 100 according to the embodiment.

As illustrated in FIG. 1, the actuator 100 includes a vibration plate 20 and a piezoelectric element 30. The actuator 100 is provided on a substrate 10.

The substrate 10 is, for example, a silicon substrate. In the illustrated example, the substrate 10 is formed with opening portions 12. When the actuator 100 is applied to a liquid ejection head, the opening portion 12 serves as a pressure generation chamber that stores a liquid ejected from the liquid ejection head and that applies a pressure to the supplied liquid.

The vibration plate 20 is provided on the substrate 10. The vibration plate 20 is provided between the substrate 10 and the piezoelectric element 30. In the illustrated example, the vibration plate 20 closes the opening portion 12. The vibration plate 20 includes, for example, a first layer 22 provided on the substrate 10 and a second layer 24 provided on the first layer 22. The first layer 22 is, for example, a silicon oxide layer. The second layer 24 is, for example, a zirconium oxide layer. The vibration plate 20 has flexibility. The vibration plate 20 is deformed in accordance with a deformation of the piezoelectric element 30.

The piezoelectric element 30 is provided above the vibration plate 20. In the illustrated example, the piezoelectric element 30 is directly provided on the vibration plate 20. The piezoelectric element 30 includes, for example, a first electrode 32, a seed layer 34, a piezoelectric layer 36, and a second electrode 38.

In the description of the present disclosure, when the word “above” is used, for example, in a statement such as “above a specific object (hereinafter, referred to as “A”), another specific object (hereinafter, referred to as “B”) is formed”, the word “above” is used to include a case in which B is directly formed at A and a case in which B is formed at A via another object.

The first electrode 32 is provided above the vibration plate 20. In the illustrated example, the first electrode 32 is directly provided on the vibration plate 20. The first electrode 32 is provided between the vibration plate 20 and the seed layer 34. A shape of the first electrode 32 is, for example, a layer. A thickness of the first electrode 32 is, for example, 3 nm or more and 300 nm or less. The first electrode 32 is, for example, a metal layer such as a platinum layer, an iridium layer, a titanium layer, or a ruthenium layer, or a conductive oxide layer thereof. The first electrode 32 may have a structure in which a plurality of layers exemplified above are laminated. The first electrode 32 may be formed by laminating a platinum layer and an iridium layer from a vibration plate 20 side. The first electrode 32 is one electrode for applying a voltage to the piezoelectric layer 36.

Although not illustrated, an adhesion layer may be provided between the vibration plate 20 and the first electrode 32 in order to improve adhesion between the vibration plate 20 and the first electrode 32. The adhesion layer is, for example, a titanium layer or a titanium oxide layer.

The seed layer 34 is provided on the first electrode 32. The seed layer 34 is provided between the first electrode 32 and the piezoelectric layer 36. In the illustrated example, the seed layer 34 is further provided on the vibration plate 20. A thickness of the seed layer 34 is, for example, 5 nm or more and 100 nm or less, and preferably 10 nm or more and 50 nm or less.

The seed layer 34 is, for example, a composite oxide having a perovskite structure containing bismuth (Bi), iron (Fe), and titanium (Ti). The seed layer 34 may be a bismuth ferrate titanate (Bi(Fe, Ti)O₃:BFT) layer. The seed layer 34 may be a BFT layer to which lead (Pb) or the like is added. When lead is added, a content of lead in the seed layer 34 is 0.1 mass % or less. Since the seed layer 34 has the same perovskite structure as the piezoelectric layer 36, an orientation, a lattice constant, and a crystal structure of the piezoelectric layer 36 can be easily controlled.

The piezoelectric layer 36 is provided above the first electrode 32. In the illustrated example, the piezoelectric layer 36 is provided on the first electrode 32 via the seed layer 34. The piezoelectric layer 36 is directly provided on the seed layer 34. The piezoelectric layer 36 is provided between the seed layer 34 and the second electrode 38. The piezoelectric layer 36 is formed by, for example, laminating a plurality of crystal layers. A thickness of the piezoelectric layer 36 is, for example, 100 nm or more and 3 μm or less, and preferably 200 nm or more and 2 μm or less.

The piezoelectric layer 36 contains a composite oxide having a perovskite structure. The piezoelectric layer 36 may be made of a composite oxide having a perovskite structure. The composite oxide may be consisted by a ferroelectric. A “ferroelectric” refers to a substance in which electric dipoles are aligned even without an external electric field and directions of the dipoles can be changed by an electric field.

The piezoelectric layer 36 contains, for example, potassium (K), sodium (Na), and niobium (Nb). The piezoelectric layer 36 is, for example, a potassium sodium niobate ((K,Na)NbO₃:KNN) layer. The piezoelectric layer 36 may be a KNN layer to which an additive such as manganese (Mn) is added. If the piezoelectric layer 36 is the KNN layer, an environmentally friendly lead-free piezoelectric layer 36 can be formed.

The piezoelectric layer 36 is not limited to the KNN layer. The piezoelectric layer 36 may be a lead-based piezoelectric layer such as a lead zirconate titanate (Pb(Zr,Ti)O₃:PZT) layer or a lead zirconate titanate niobate (Pb(Zr,Ti,Nb)O₃:PZTN) layer. The piezoelectric layer 36 may be a lead-free piezoelectric layer other than the KNN layer.

The lattice constant in an in-plane direction of the piezoelectric layer 36 is, for example, smaller than a lattice constant in an in-plane direction of the seed layer 34. The “in-plane direction” is a direction orthogonal to a thickness direction of the substrate 10. When a material constituting the piezoelectric layer 36 is KNN, the lattice constant in the in-plane direction is a length in an a-axis direction.

A tensile stress is generated in the piezoelectric layer 36. The tensile stress of the piezoelectric layer 36 is, for example, 261 MPa or more and 1000 MPa or less. The tensile stress of the piezoelectric layer 36 is caused by, for example, a difference between the lattice constant in the in-plane direction of the piezoelectric layer 36 and the lattice constant in the in-plane direction of the seed layer 34.

The second electrode 38 is provided above the piezoelectric layer 36. In the illustrated example, the second electrode 38 is directly provided on the piezoelectric layer 36. A shape of the second electrode 38 is, for example, a layer. A thickness of the second electrode 38 is, for example, 3 nm or more and 300 nm or less. The second electrode 38 is, for example, a metal layer such as a platinum layer, an iridium layer, a titanium layer, or a ruthenium layer, or a conductive oxide layer thereof. The second electrode 38 may have a structure in which a plurality of layers exemplified above are laminated. The second electrode 38 is one electrode for applying a voltage to the piezoelectric layer 36.

### 1.2 Hysteresis Curve

FIG. 2 is a diagram illustrating a hysteresis curve of the piezoelectric layer 36. An electric field E on a horizontal axis illustrated in FIG. 2 is an electric field generated in the piezoelectric layer 36 by applying a voltage between the first electrode 32 and the second electrode 38. A polarization amount P on a vertical axis illustrated in FIG. 2 is an amount of poles generated in the piezoelectric layer 36 due to the electric field E.

A residual polarization Pr is the polarization amount P when the electric field E is 0 kV/cm. A spontaneous polarization Ps is a polarization amount except for components due to a contribution of dielectric constant when the ferroelectric constituting the piezoelectric layer 36 is completely polarized. In the following, an intercept of a tangent T of the hysteresis curve at the maximum electric field Emax, that is, E=0, is defined as the spontaneous polarization Ps. The maximum electric field Emax is an electric field generated in the piezoelectric layer 36 when the applied voltage between the first electrode 32 and the second electrode 38 is maximized.

The residual polarization Pr is, for example, 12.2 μC/cm² or less, and preferably 12.0 μC/cm² or less. The residual polarization Pr is, for example, 0.8 μC/cm² or more, preferably 1.0 μC/cm² or more, and more preferably 1.2 μC/cm² or more.

The spontaneous polarization Ps is larger than the residual polarization Pr. The spontaneous polarization Ps is, for example, 23.2 μC/cm² or less, and preferably 23.0 μC/cm² or less. The spontaneous polarization Ps is, for example, 5.0 μC/cm² or more, preferably 7.0 μC/cm², and more preferably 8.0 μC/cm².

The residual polarization Pr is 0.535 times or less, and preferably 0.521 times or less the spontaneous polarization Ps. The residual polarization Pr is, for example, 0.10 times or more, preferably 0.122 times or more, and more preferably 0.15 times or more the spontaneous polarization Ps.

An increase rate of a displacement amount of the vibration plate 20 when the electric field E generated in the piezoelectric layer 36 is increased by 10% from 210 kV/cm is, for example, 0.94 times or more a decrease rate of the displacement amount of the vibration plate 20 when the electric field E is decreased by 10% from 210 kV/cm. In other words, the increase rate of the displacement amount of the vibration plate 20 when the electric field E is increased from 210 kV/cm to 231 kV/cm is 0.94 times or more the decrease rate of the displacement amount of the vibration plate 20 when the electric field E is decreased from 210 kV/cm to 189 kV/cm.

### 1.3. Operation and Effect

The actuator 100 includes the vibration plate 20, the first electrode 32 provided above the vibration plate 20, the piezoelectric layer 36 that is provided above the first electrode 32 and that contains a composite oxide having a perovskite structure, and the second electrode 38 provided above the piezoelectric layer 36. The residual polarization Pr of the piezoelectric layer 36 is 0.535 times or less the spontaneous polarization Ps of the piezoelectric layer 36. Therefore, in the actuator 100, as illustrated in “Examples and Comparative Examples” described later, linearity of the hysteresis curve can be improved. Therefore, even when the applied voltage between the first electrode 32 and the second electrode 38 is increased, an increment of the displacement amount of the vibration plate 20 can be prevented from decreasing. Accordingly, an operating voltage can be easily designed.

In the actuator 100, the residual polarization Pr is 12.2 μC/cm² or less, and the spontaneous polarization Ps is 23.2 μC/cm² or less. Therefore, in the actuator 100, the residual polarization Pr can be set to 0.535 times or less the spontaneous polarization Ps.

In the actuator 100, the increase rate of the displacement amount of the vibration plate 20 when the electric field E generated in the piezoelectric layer 36 is increased by 10% from 210 kV/cm is 0.94 times or more the decrease rate of the displacement amount of the vibration plate 20 when the electric field E is decreased by 10% from 210 kV/cm. Therefore, in the actuator 100, the linearity of the hysteresis curve can be improved.

In the actuator 100, the tensile stress of the piezoelectric layer 36 is 261 MPa or more. Therefore, in the actuator 100, a component oriented in a film thickness direction in a polarization generated in the piezoelectric layer 36 can be reduced. Accordingly, the residual polarization Pr can be reduced and the linearity of the hysteresis curve can be improved.

The actuator 100 includes the seed layer 34 provided between the first electrode 32 and the piezoelectric layer 36, and the lattice constant in the in-plane direction of the piezoelectric layer 36 is smaller than the lattice constant in the in-plane direction of the seed layer 34. Therefore, in the actuator 100, a tensile stress can be generated in the piezoelectric layer 36.

### 2. Method for Manufacturing Actuator

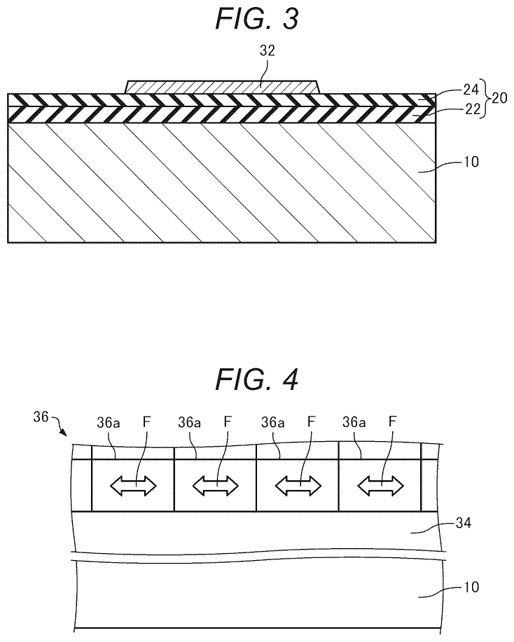

Next, a method for manufacturing the actuator 100 according to the embodiment will be described with reference to the drawings. FIG. 3 is a cross-sectional view schematically illustrating steps of manufacturing the actuator 100 according to the embodiment.

As illustrated in FIG. 3, the first layer 22 is formed at the substrate 10. Next, the second layer 24 is formed at the first layer 22. The first layer 22 is formed by, for example, thermally oxidizing the substrate 10 which is a silicon substrate. The second layer 24 is formed by forming a zirconium layer on the first layer 22 by a sputtering method or the like, and then thermally oxidizing the zirconium layer. By this step, the vibration plate 20 including the first layer 22 and the second layer 24 can be formed.

Next, the first electrode 32 is formed at the vibration plate 20. The first electrode 32 is formed by, for example, a sputtering method or a vacuum deposition method. Next, the first electrode 32 is patterned. The patterning is performed by, for example, photolithography and etching.

As illustrated in FIG. 1, the seed layer 34 is formed at the first electrode 32. The seed layer 34 is formed by a chemical solution deposition (CSD) method such as a sol-gel method or a metal organic deposition (MOD) method. In the following, a method for forming the seed layer 34, which is the BFT layer, will be described.

For example, a precursor solution is prepared by dissolving or dispersing a metal complex containing bismuth, a metal complex containing iron, and a metal complex containing tantalum in an organic solvent. Examples of the metal complex containing bismuth include bismuth 2-ethylhexanoate and bismuth acetate. Examples of the metal complex containing iron include iron 2-ethylhexanoate, iron acetate, and tris(acetylacetonate) iron. Examples of the metal complex containing tantalum include pentaethoxytantalum. Two or more types of metal complexes may be used in combination. For example, as a metal complex containing bismuth, bismuth 2-ethylhexanoate and bismuth acetate may be used in combination.

Examples of the organic solvent used for preparing the precursor solution include propanol, butanol, pentanol, hexanol, octanol, ethylene glycol, propylene glycol, octane, decane, cyclohexane, xylene, toluene, tetrahydrofuran, acetic acid, octylic acid, 2-n-butoxyethanol, n-octane, and a mixed solvent thereof. The precursor solution may contain an additive that stabilizes dispersion of each metal complex. Examples of such an additive include 2-ethylhexanoic acid and diethanolamine.

Next, the prepared precursor solution is applied onto the first electrode 32 and the vibration plate 20 by using a spin coating method or the like to form a precursor layer. Next, the precursor layer is heated, for example, at 130° C. or higher and 250° C. or lower and dried for a certain period of time, and then the dried precursor layer is degreased by heating at, for example, 300° C. or higher and 450° C. or lower and holding the same for a certain period of time. Next, the degreased precursor layer is crystallized by firing at, for example, 550° C. or higher and 800° C. or lower.

A heating device used for drying and degreasing the precursor layer is, for example, a hot plate. A heating device used for firing the precursor layer is, for example, a lamp annealing device.

By the above steps, the seed layer 34 can be formed.

Next, the piezoelectric layer 36 is formed at the seed layer 34. The piezoelectric layer 36 is formed by, for example, the same chemical solution deposition method as that of the seed layer 34. In the following, a method for forming the piezoelectric layer 36, which is the KNN layer to which manganese is added, will be described.

For example, a precursor solution is prepared by dissolving or dispersing a metal complex containing potassium, a metal complex containing sodium, a metal complex containing niobium, and a metal complex containing manganese in an organic solvent.

Examples of the metal complex containing potassium include potassium 2-ethylhexanoate and potassium acetate. Examples of the metal complex containing sodium include sodium 2-ethylhexanoate and sodium acetate. Examples of the metal complex containing niobium include niobium 2-ethylhexanoate, pentaethoxyniobium, and pentabutoxyniobium. Examples of the metal complex containing manganese include manganese 2-ethylhexanoate. Two or more types of metal complexes may be used in combination. As the solvent, for example, the above materials for forming the seed layer 34 are used.

Next, the prepared precursor solution is applied onto the first electrode 32 by using a spin coating method or the like to form a precursor layer. Next, the precursor layer is heated, for example, at 130° C. or higher and 250° C. or lower and dried for a certain period of time, and then the dried precursor layer is degreased by heating at, for example, 300° C. or higher and 450° C. or lower and holding the same for a certain period of time. Next, the degreased precursor layer is crystallized by firing at, for example, 550° C. or higher and 800° C. or lower to form a crystal layer. As a device for heating the precursor layer, for example, the above device for forming the seed layer 34 is used.

Next, the crystal layer is cooled. Specifically, the crystal layer is cooled at a rate of 3.0° C./sec or more, and preferably at a rate of 5.0° C./sec or more. By cooling the crystal layer at such a rate, as illustrated in FIG. 4, a tensile stress can be generated in a crystal structure 36a of the crystal layer.

For example, when the crystal layer is slowly cooled at 0.3° C./sec, since the crystal layer is cooled after heat of the crystal layer is sufficiently transferred to the substrate, the substrate is also shrunk together with the crystal layer. Therefore, a tensile stress is unlikely to occur in the crystal layer.

Meanwhile, when the crystal layer is rapidly cooled, since the crystal layer is cooled before the heat of the crystal layer is sufficiently transferred to the substrate, the crystal layer is selectively shrunk. Therefore, the crystal layer is pulled in the in-plane direction by the substrate, generating a tensile stress F. When the tensile stress F is large, the residual polarization Pr decreases and the linearity of the hysteresis curve is improved. For cooling the crystal layer, for example, air cooling or water cooling with circulating cooling water is used. FIG. 4 is a diagram illustrating the tensile stress F generated in the crystal structure 36a, and illustrates the crystal structure 36a in a simplified manner.

The above series of steps from the application of the precursor solution to the firing of the precursor layer are repeated a plurality of times. Accordingly, the piezoelectric layer 36 including a plurality of crystal layers can be formed. The number of crystal layers constituting the piezoelectric layer 36 is, for example, 5 or more and 20 or less, and preferably 10 or more and 15 or less.

By the above steps, the piezoelectric layer 36 can be formed.

The method for forming the piezoelectric layer 36 and the seed layer 34 is not limited to the chemical solution deposition method, and may be a physical vapor deposition (PVD) method. Examples of the physical vapor deposition method include the sputtering method and laser ablation.

Next, the second electrode 38 is formed at the piezoelectric layer 36. The second electrode 38 is formed by, for example, a sputtering method or a vacuum deposition method. Next, the second electrode 38, the piezoelectric layer 36, and the seed layer 34 are patterned. The patterning is performed by, for example, photolithography and etching. By collectively patterning the second electrode 38, the piezoelectric layer 36, and the seed layer 34, the manufacturing steps can be reduced. The second electrode 38, the piezoelectric layer 36, and the seed layer 34 may be patterned in separate steps.

Next, a lower surface of the substrate 10 is patterned to form the opening portion 12. The patterning is performed by, for example, photolithography and etching. Before patterning, the lower surface of the substrate 10 may be ground and polished.

By the above steps, the actuator 100 can be manufactured.

### 3. Liquid Ejection Head

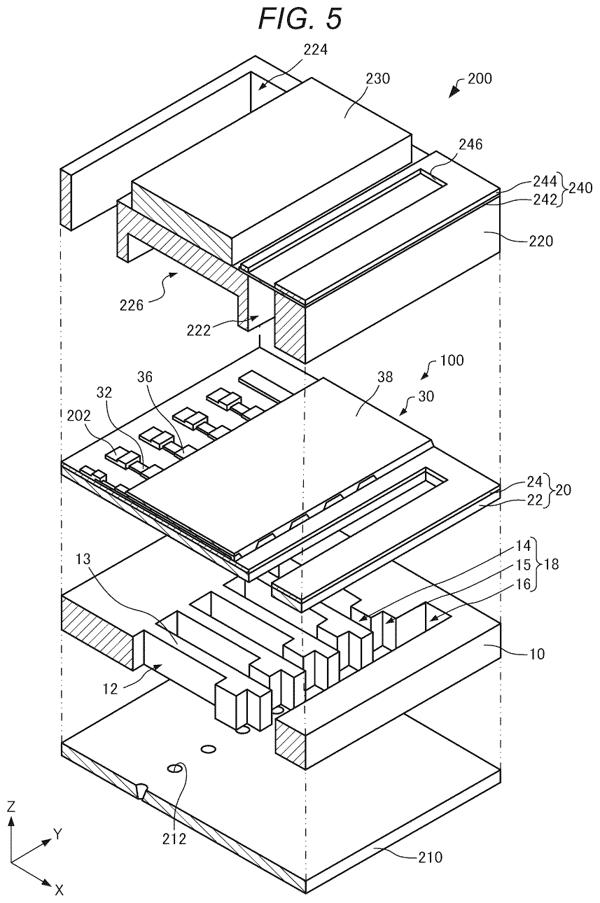

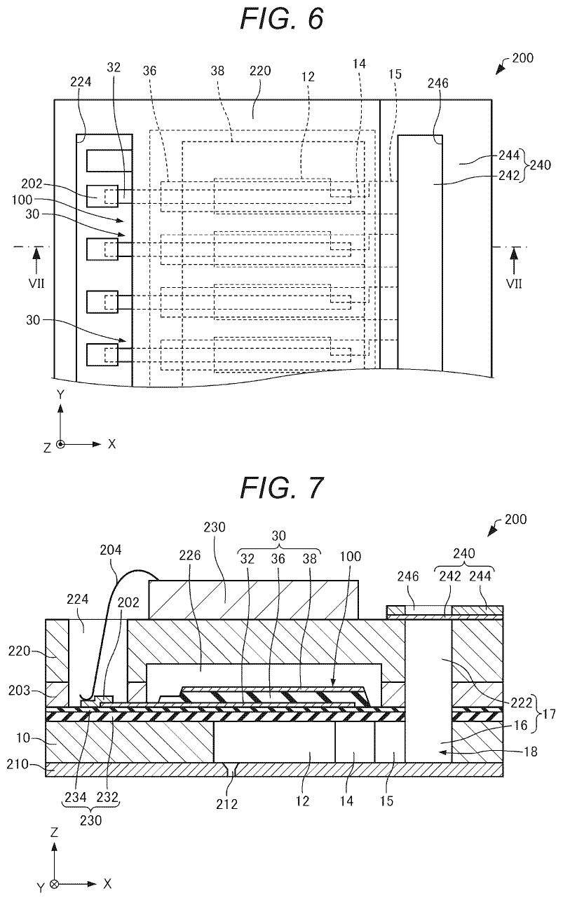

Next, a liquid ejection head according to the embodiment will be described with reference to the drawings. FIG. 5 is an exploded perspective view schematically illustrating a liquid ejection head 200 according to the embodiment. FIG. 6 is a plan view schematically illustrating the liquid ejection head 200 according to the embodiment. FIG. 7 is a cross-sectional view taken along a line VII-VII illustrated in FIG. 6, schematically illustrating the liquid ejection head 200 according to the embodiment. FIGS. 5 to 7 illustrate an X-axis, a Y-axis, and a Z-axis as three axes orthogonal to each other. In FIGS. 5 and 7, the piezoelectric element 30 is illustrated in a simplified manner.

As illustrated in FIGS. 5 to 7, the liquid ejection head 200 includes, for example, the actuator 100, a nozzle plate 210, a protective substrate 220, a circuit substrate 230, and a compliance substrate 240. For convenience, in FIG. 6, the circuit substrate 230 is not illustrated.

The opening portions 12 each serving as a pressure generation chamber are formed in the substrate 10 of the actuator 100. The opening portions 12 are partitioned by a plurality of partition walls 13. A volume of the opening portion 12 changes as the vibration plate 20 is displaced by the piezoelectric element 30.

First communication paths 14 and second communication paths 15 are formed in the substrate 10. In the illustrated example, the first communication path 14 and the second communication path 15 are formed at an end of the opening portion 12 in a +X-axis direction. The first communication path 14 is implemented in a manner that an opening area is reduced by narrowing the end of the opening portion 12 in the +X-axis direction from a Y-axis direction. A width of the second communication path 15 in the Y-axis direction is, for example, the same as a width of the opening portion 12 in the Y-axis direction. A third communication path 16 communicating with the plurality of second communication paths 15 is formed in the +X-axis direction of the second communication path 15. The third communication path 16 constitutes a part of a manifold 17. The manifold 17 serves as a common liquid chamber for the respective opening portions 12. In this way, a supply flow path 18 including the first communication path 14, the second communication path 15, and the third communication path 16, and the opening portions 12 are formed in the substrate 10. The substrate 10 is a flow path forming substrate. The supply flow path 18 communicates with the opening portion 12 and supplies liquid to the opening portion 12.

The nozzle plate 210 is provided on one surface of the substrate 10. A material for the nozzle plate 210 is, for example, steel use stainless (SUS). The nozzle plate 210 is bonded to the substrate 10 by, for example, an adhesive or a thermal welding film. The substrate 10 is provide between the nozzle plate 210 and the vibration plate 20. A plurality of nozzle holes 212 are formed in the nozzle plate 210 along the Y-axis. The nozzle hole 212 communicates with the opening portion 12 and ejects liquid.

In the liquid ejection head 200, the vibration plate 20 and the first electrode 32 are displaced by the deformation of the piezoelectric layer 36 having electromechanical conversion characteristics. For example, a plurality of piezoelectric elements 30 are provided. The number of the piezoelectric elements 30 is not particularly limited.

The first electrode 32 is formed as an individual electrode independent for each opening portion 12. A size of the first electrode 32 in the Y-axis direction is, for example, smaller than a size of the opening portion 12 in the Y-axis direction. A size of the first electrode 32 in an X-axis direction is, for example, larger than a size of the opening portion 12 in the X-axis direction. In the X-axis direction, both ends of the first electrode 32 are positioned in a manner of sandwiching both ends of the opening portion 12. A lead electrode 202 is connected to an end of the first electrode 32 in a −X-axis direction.

A size of the piezoelectric layer 36 in the Y-axis direction is, for example, larger than the size of the first electrode 32 in the Y-axis direction. A size of the piezoelectric layer 36 in the X-axis direction is, for example, larger than the size of the opening portion 12 in the X-axis direction. An end of the first electrode 32 in the +X-axis direction is positioned, for example, between an end of the piezoelectric layer 36 in the +X-axis direction and the end of the opening portion 12 in the +X-axis direction. The end of the first electrode 32 in the +X-axis direction is covered by the piezoelectric layer 36. An end of the piezoelectric layer 36 in the −X-axis direction is positioned, for example, between the end of the first electrode 32 in the −X-axis direction and an end of the opening portion 12 in the −X-axis direction. The end of the first electrode 32 in the −X-axis direction is not covered by the piezoelectric layer 36.

The second electrode 38 is, for example, provided continuously on the piezoelectric layer 36 and the vibration plate 20. In the illustrated example, the second electrode 38 is formed as a common electrode common to the plurality of piezoelectric elements 30.

The protective substrate 220 is bonded to the vibration plate 20 by an adhesive 203. The protective substrate 220 is provided with a through hole 222. In the illustrated example, the through hole 222 penetrates the protective substrate 220 in a Z-axis direction and communicates with the third communication path 16. The through hole 222 and the third communication path 16 constitute the manifold 17 serving as the common liquid chamber for the opening portions 12. Further, the protective substrate 220 is formed with a through hole 224 that penetrates the protective substrate 220 in the Z-axis direction. An end of the lead electrode 202 is positioned in the through hole 224.

The protective substrate 220 is formed with an opening portion 226. The opening portion 226 is a space for not inhibiting the driving of the piezoelectric element 30. The opening portion 226 may or may not be sealed.

The circuit substrate 230 is provided on the protective substrate 220. The circuit substrate 230 includes a semiconductor integrated circuit (IC) for driving the piezoelectric element 30. The circuit substrate 230 and the lead electrode 202 are electrically connected via a connection wiring 204.

The compliance substrate 240 is provided on the protective substrate 220. The compliance substrate 240 includes a sealing layer 242 provided on the protective substrate 220 and a fixing plate 244 provided on the sealing layer 242. The sealing layer 242 is a layer for sealing the manifold 17. The sealing layer 242 has, for example, flexibility. A through hole 246 is formed in the fixing plate 244. The through hole 246 penetrates the fixing plate 244 in the Z-axis direction. The through hole 246 is provided at a position overlapping the manifold 17 when viewed in the Z-axis direction.

### 4. Printer

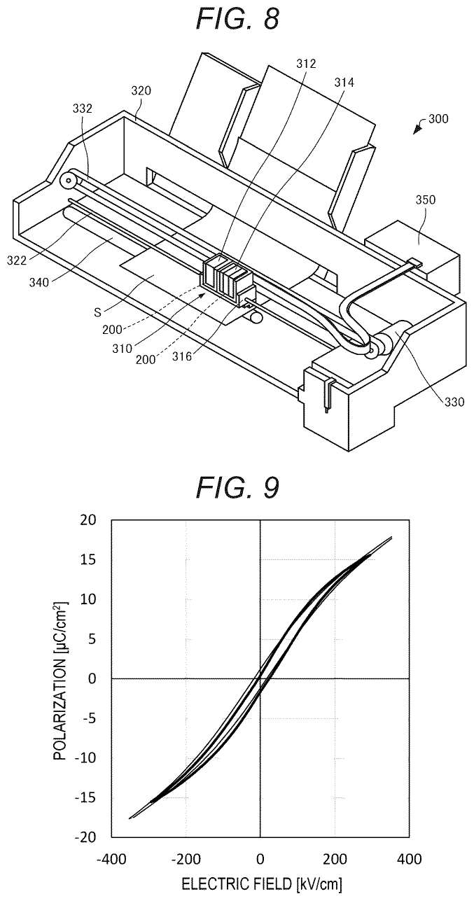

Next, a printer according to the embodiment will be described with reference to the drawings. FIG. 8 is a perspective view schematically illustrating a printer 300 according to the embodiment.

The printer 300 is an ink jet printer. As illustrated in FIG. 8, the printer 300 includes a head unit 310. The head unit 310 includes, for example, the liquid ejection heads 200. The number of liquid ejection heads 200 is not particularly limited. The head unit 310 is detachably provided with cartridges 312 and 314 constituting a supply unit. A carriage 316 on which the head unit 310 is mounted is provided on a carriage shaft 322 attached to a device main body 320 so as to be movable in an axial direction, and ejects a liquid supplied from a liquid supply unit.

The liquid refers to any material in a liquid phase, and liquid materials such as sols and gels are also included in the liquid. The liquid includes not only the liquid as a state of a substance, but also a liquid in which particles of a functional material made of a solid such as a pigment or a metal particle are dissolved, dispersed, or mixed in a solvent. Representative examples of the liquid include ink and liquid crystal emulsions. The term ink includes various types of liquid compositions such as general water-based ink, oil-based ink, gel ink, and hot melt ink.

In the printer 300, a driving force of a driving motor 330 is transmitted to the carriage 316 via a plurality of gears (not illustrated) and a timing belt 332. Accordingly, the carriage 316 on which the head unit 310 is mounted is moved along the carriage shaft 322. Meanwhile, the device main body 320 is provided with a conveyance roller 340 serving as a conveyance mechanism for moving a sheet S, which is a recording medium such as paper, with respect to the liquid ejection head 200. The conveyance mechanism that conveys the sheet S is not limited to the conveyance roller, and may be a belt, a drum, or the like.

The printer 300 includes a printer controller 350 serving as a control unit that controls the liquid ejection head 200 and the conveyance roller 340. The printer controller 350 is electrically connected to the circuit substrate 230 of the liquid ejection head 200. The printer controller 350 includes, for example, a random access memory (RAM) that temporarily stores various data, a read only memory (ROM) that stores control programs and the like, a central processing unit (CPU), and a drive signal generation circuit that generates drive signals to be supplied to the liquid ejection head 200.

### 5. EXAMPLES AND COMPARATIVE EXAMPLE

### 5.1. Preparation of Samples

### 5.1.1. Example 1

A front surface of a single crystal silicon substrate was thermally oxidized to form a SiO₂ layer having a thickness of 1460 nm. Next, a Zr film having a thickness of 400 nm was formed by a direct current (DC) sputtering method, and a ZrO₂ layer was formed by a heat treatment at 850° C. Accordingly, a vibration plate including the SiO₂ layer and the ZrO₂ layer was formed.

Next, as a first electrode, a Ti layer, a Pt layer, and an Ir layer having thicknesses of 20 nm, 80 nm, and 5 nm, respectively, were formed by a DC sputtering method.

Next, a seed layer was formed. Specifically, a BFT precursor solution was prepared to have a molar ratio of Bi/Fe/Ti=110/50/50 by using bismuth acetate, iron acetate, and titanium tetra-i-propoxide. The precursor solution was spin-coated to form a film having a thickness of 20 nm, and then lamp annealed in an oxygen atmosphere at 650° C. for 3 minutes to obtain a BFT crystal layer.

Next, a piezoelectric layer was formed. Specifically, a KNN precursor solution was prepared to have a molar ratio of K/Na/Nb=52/52/100 by using potassium 2-ethylhexanoate, sodium 2-ethylhexanoate, and niobium 2-ethylhexanoate. Further, a solution containing manganese 2-ethylhexanoate was used to contain 0.2 wt % MnO as an additive. Such a precursor solution was spin-coated to form a film having a thickness of 70 nm, and then lamp annealed in an oxygen atmosphere at 700° C. for 3 minutes to obtain a KNN crystal layer. Thereafter, the KNN crystal layer was cooled at a rate of 5° C./sec by air cooling and water cooling with circulating cooling water. The above steps were repeated 12 times to form a piezoelectric layer having a thickness of 840 nm.

Next, a Pt layer having a thickness of 50 nm was formed as a second electrode by a DC sputtering method.

Next, the second electrode, the piezoelectric layer, and the seed layer were patterned by ion milling to prepare a piezoelectric element.

Next, a back surface of the single crystal silicon substrate was ground and polished to a thickness of about 400 μm. Next, a chromium oxide layer having a thickness of 60 nm and a chromium layer having a thickness of 100 nm were formed at the polished surface. Next, the chromium oxide layer and the chromium layer were patterned by wet etching. Further, the single crystal silicon substrate was patterned by wet etching to form an opening portion.

In this way, an actuator according to Example 1 was formed.

### 5.1.2. Example 2

A front surface of a single crystal silicon substrate was thermally oxidized to form a SiO₂ layer having a thickness of 1870 nm as a vibration plate. Next, a Pt layer having a thickness of 200 nm was formed as a first electrode by a DC sputtering method.

Next, a piezoelectric layer having a thickness of 1000 nm was formed by an RF sputtering method using a KNN target prepared to have a molar ratio of K/Na/Nb=35/65/100.

Next, a Pt layer having a thickness of 100 nm was formed as a second electrode by a DC sputtering method.

The subsequent steps were the same as those in Example 1.

In this way, an actuator according to Example 2 was formed.

### 5.1.3. Comparative Example 1

A front surface of a single crystal silicon substrate was thermally oxidized to form a SiO₂ layer having a thickness of 1460 nm. Next, a Zr film having a thickness of 400 nm was formed by a DC sputtering method, and a ZrO₂ layer was formed by a heat treatment at 850° C. Accordingly, a vibration plate including the SiO₂ layer and the ZrO₂ layer was formed.

Next, as a first electrode, a Ti layer, a Pt layer, an Ir layer, and a Ti layer having thicknesses of 20 nm, 80 nm, 5 nm, and 4 nm, respectively, were formed by a DC sputtering method.

Next, a piezoelectric layer was formed. Specifically, a PZT precursor solution was prepared to have a molar ratio of Pb/Zr/Ti=118/52/48 by using lead acetate, zirconium butoxide, and titanium tetra-i-propoxide. The precursor solution was spin-coated to form a film, and then lamp annealed in a nitrogen atmosphere at 737° C. for 5 minutes to obtain a PZT crystal film. The above steps were repeated 6 times to form a piezoelectric layer having a thickness of 1200 nm.

Next, a second electrode was formed. Specifically, an Ir layer and a Ti layer having thicknesses of 5 nm and 4 nm, respectively, were formed by a DC sputtering method. Next, lamp annealing was performed in a nitrogen atmosphere at 740° C. for 8 minutes to form an Ir layer and a Ti layer of 6 nm and 25 nm, respectively.

The subsequent steps were the same as those in Example 1.

In this way, an actuator according to comparative Example 1 was formed.

### 5.2. Experimental Method

### 5.2.1. Spontaneous Polarization and Residual Polarization

As measurement devices, a ferroelectric tester FCE manufactured by Toyo Corporation and a voltage amplifier F10A manufactured by Toyo Corporation were used. A triangular wave having a frequency of 66 Hz and an electric field of 290 kV/cm was applied to a piezoelectric layer having an area of 97680 μm² in a plan view to obtain a hysteresis curve. Fitting was performed using a modified Miller model obtained by modifying a model using Miller to calculate the spontaneous polarization and the residual polarization. The modified Miller model is expressed by the following Formulas (1) to (3).

$$P = Ps tan h \frac{V - Vc}{2 Vc \cdot δ} + \frac{Pm - Ps}{Vm} V \qquad ( 1 )$$

$$δ = {( \frac{Ps - Pr}{Ps + Pr} )}^{n} \qquad ( 2 )$$

$$n = - \frac{log ( - log \frac{Ps - Pr}{Ps + Pr} )}{log \frac{Ps - Pr}{Ps + Pr}} \qquad ( 3 )$$

In Formulas (1) to (3), P is a polarization amount, Ps is a spontaneous polarization, Pr is a residual polarization, V is a voltage, Vc is a coercive voltage, Vm is a maximum applied voltage, and Pm is a polarization amount when Vm is applied.

### 5.2.2. Displacement Amount

As devices for measuring the displacement amount of the vibration plate, an arbitrary waveform generator AFG3022C manufactured by Tektronix, a voltage amplifier HSA4011 manufactured by NF CORPORATION, an oscilloscope HDO4024 manufactured by Teledyne Lecroy, and a laser displacement meter NLV-2500 manufactured by Polytec were used. A square wave having a voltage width of 5V to 35V, which was output from the arbitrary waveform generator and amplified ten times by the voltage amplifier, was applied to a piezoelectric layer having the same area as the above. The displacement amount of the vibration plate was detected by the laser displacement meter, and the displacement amount was converted into a voltage and input into the oscilloscope. A minimum voltage was adjusted to maximize the displacement amounts in Examples 1 and 2 and Comparative Example 1. With 210 kV/cm as a reference, a decrease rate of the displacement amount when the electric field was decreased by 10% and an increase rate of the displacement amount when the electric field was increased by 10% were respectively evaluated, and a value obtained by dividing the latter by the former was used as an evaluation index for the linearity of the hysteresis curve. The closer this index is to 1, the higher the linearity can be said to be.

### 5.2.3. Tensile Stress

Tensile stresses of the piezoelectric layers according to Examples 1 and 2 and Comparative Example 1 were obtained based on warpage amounts of laminated samples by using a thin film stress measurement device FLX-2908 (manufactured by KLA-Tencor Corporation).

Specifically, each layer was laminated on an entire surface of a silicon substrate having a diameter of 150 mm, except for a range of 1 mm in an outer periphery, as described in “Preparation of Samples” above, and warpage amounts of the laminated sample before and after forming the piezoelectric layer were measured. Specifically, the warpage amount was measured by measuring a shape of a range, except for the range of 10 mm in the outer periphery, on a straight line including a center of the laminated sample. In the cases of Examples 1 and 2 and Comparative Example 1, since the center was recessed, a difference in height in a direction perpendicular to a sample surface between both ends of the straight line and the center is the warpage amount.

When the warpage amount is sufficiently shorter than 130 mm which is the range in which the shape is measured, the stress of the piezoelectric layer can be obtained by the following Formula (4).

$$σ ≅ \frac{4 {E}_{S} {t}_{S}^{2}}{3 ( 1 - v ) {t}_{F} {L}^{2}} ( {z}_{B} - {z}_{A} ) \qquad ( 4 )$$

In Formula (4), σ is a tensile stress, Eₛ is a Young's modulus of the substrate, v is a Poisson's ratio of the substrate, L is a length of a measurement range, tₛ is a thickness of the substrate, t_{F} is a thickness of the piezoelectric layer, z_{B} is a warpage amount of the laminated sample before the piezoelectric layer is formed, and z_{A} is a warpage amount of the laminated sample after the piezoelectric layer is formed.

### 5.2.4. Lattice Constant

In Example 1 and Comparative Example 1, lattice constants of the piezoelectric layer and a base layer were measured. The base layer is a layer immediately below the piezoelectric layer, and is a BFT layer in Example 1 and a Pt layer in Comparative Example 1. A thin film X-ray diffractometer (D8 Discover, manufactured by Bruker AXS) was used, an X-ray diffraction peak of a crystal was obtained by an ordinary 2θ-ω method using a Cu-Kα line, and the lattice constant was obtained from a Bragg formula.

### 5.3. Experimental Results

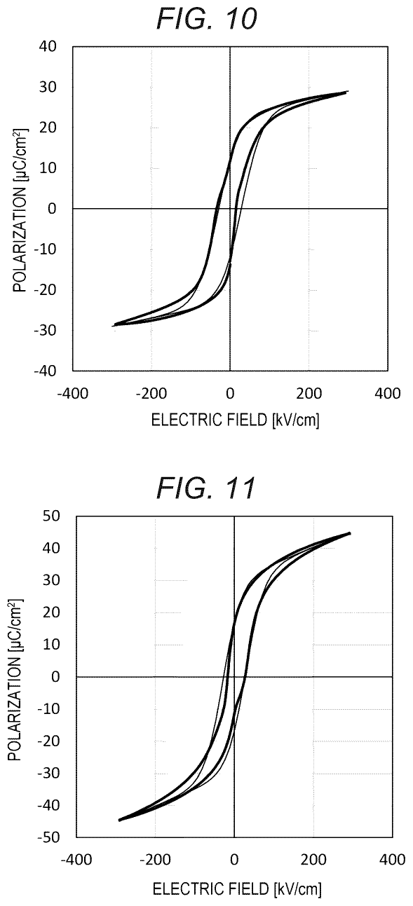

FIG. 9 illustrates a hysteresis curve of Example 1. FIG. 10 illustrates a hysteresis curve of Example 2. FIG. 11 illustrates a hysteresis curve of Comparative Example 1. In FIGS. 9 to 11, actual measurement values were indicated by thick lines, and fitting data was indicated by thin lines.

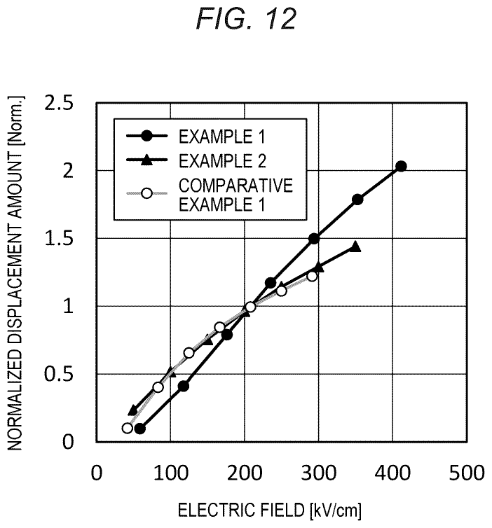

FIG. 12 is a graph illustrating a relation between the electric field generated in the piezoelectric layer and the displacement amount of the vibration plate in Examples 1 and 2 and Comparative Example 1. A vertical axis in FIG. 12 represents the displacement amount normalized with the displacement amount of the vibration plate having an electric field of 210 kV/cm as “1”.

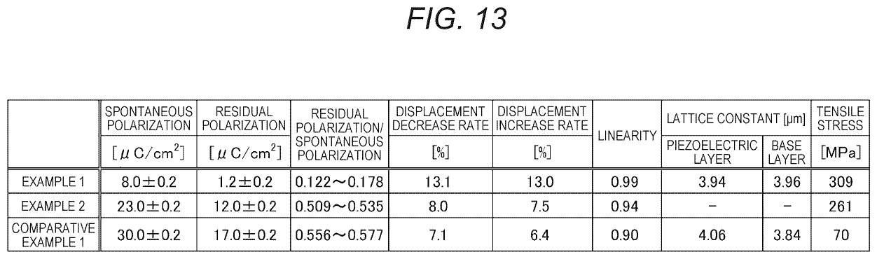

FIG. 13 is a table illustrating a list of experimental results of Examples 1 and 2 and Comparative Example 1. The “spontaneous polarization” and the “residual polarization” in FIG. 13 are obtained by adding a tolerance of “0.2” to the values read from FIGS. 9 to 11. The “residual polarization/spontaneous polarization” indicates a range in consideration of the tolerance.

As illustrated in FIG. 13, Examples 1 and 2 had higher linearity than that of Comparative Example 1. It was found that the linearity can be increased to 0.94 or more by setting the residual polarization to 0.535 times or less the spontaneous polarization.

Since the polarization amount is small at a low voltage, the vibration plate is displaced mainly due to electrostriction of the piezoelectric layer. Since the displacement amount due to the electrostriction is proportional to the square of the voltage, an increment of an external force due to the piezoelectric layer applied to the vibration plate increases as the voltage increases. It is considered that the external force is offset by a resistance force due to the increase in the displacement amount of the vibration plate, and the linearity of the hysteresis curve is improved in the entire system of the actuator.

As illustrated in FIG. 13, in Example 1, the lattice constant of the piezoelectric layer was smaller than the lattice constant of the base layer. Meanwhile, in Comparative Example 1, the lattice constant of the piezoelectric layer was larger than the lattice constant of the base layer. In Example 1, a stronger tensile stress was generated in the piezoelectric layer as compared with Comparative Example 1.

The embodiment and the modifications described above are examples, and the present disclosure is not limited thereto. For example, the embodiment and the modifications may be combined as appropriate.

The present disclosure includes substantially the same configurations as the configurations described in the embodiment, such as a configuration having the same function, method, and result and a configuration having the same object and effect. The present disclosure includes a configuration in which a non-essential portion of the configuration described in the embodiments is replaced. The present disclosure includes a configuration capable of achieving the same function and effect or a configuration capable of achieving the same object as the configuration described in the embodiments. The present disclosure includes a configuration obtained by adding a known technique to the configuration described in the embodiments.

The following contents are derived from the embodiment and the modifications described above.

An actuator according to an aspect includes:
a vibration plate;
a first electrode provided above the vibration plate;
a piezoelectric layer that is provided above the first electrode and that contains a composite oxide having a perovskite structure; and
a second electrode provided above the piezoelectric layer, in which
a residual polarization of the piezoelectric layer is 0.535 times or less a spontaneous polarization of the piezoelectric layer.

According to the actuator, even when the applied voltage between the first electrode and the second electrode is increased, an increment of a displacement amount of the vibration plate can be prevented from decreasing.

In the actuator according to an aspect,
the residual polarization may be 12.2 μC/cm² or less, and
the spontaneous polarization may be 23.2 μC/cm² or less.

According to the actuator, the residual polarization can be set to 0.535 times or less the spontaneous polarization.

In the actuator according to an aspect,
an increase rate of the displacement amount of the vibration plate when an electric field generated in the piezoelectric layer is increased by 10% from 210 kV/cm may be 0.94 times or more a decrease rate of the displacement amount of the vibration plate when the electric field is decreased by 10% from 210 kV/cm.

According to the actuator, linearity of a hysteresis curve can be improved.

In the actuator according to an aspect,
a tensile stress of the piezoelectric layer may be 261 MPa or more.

According to the actuator, the residual polarization can be reduced and the linearity of the hysteresis curve can be improved.

In the actuator according to an aspect, further including:
a seed layer provided between the first electrode and the piezoelectric layer, in which
a lattice constant in an in-plane direction of the piezoelectric layer may be smaller than a lattice constant in an in-plane direction of the seed layer.

According to the actuator, a tensile stress can be generated in the piezoelectric layer.

A liquid ejection head according to an aspect includes:
the actuator according to the aspect; and
a nozzle plate formed with a nozzle hole, in which
a substrate is provided between the nozzle plate and the vibration plate and is formed with a pressure generation chamber communicating with the nozzle hole.

A printer according to an aspect includes:
the liquid ejection head;
a conveyance mechanism configured to move a recording medium with respect to the liquid ejection head; and
a control unit configured to control the liquid ejection head and the conveyance mechanism.

What is claimed is:

1. An actuator comprising:
a vibration plate;
a first electrode provided above the vibration plate;
a piezoelectric layer provided above the first electrode and containing a composite oxide having a perovskite structure; and
a second electrode provided above the piezoelectric layer, wherein
a residual polarization of the piezoelectric layer is 0.535 times or less a spontaneous polarization of the piezoelectric layer.

2. The actuator according to claim 1, wherein
the residual polarization is 12.2 μC/cm² or less, and
the spontaneous polarization is 23.2 μC/cm² or less.

3. The actuator according to claim 1, wherein
an increase rate of a displacement amount of the vibration plate when an electric field generated in the piezoelectric layer is increased by 10% from 210 kV/cm is 0.94 times or more a decrease rate of the displacement amount of the vibration plate when the electric field is decreased by 10% from 210 kV/cm.

4. The actuator according to claim 1, wherein
a tensile stress of the piezoelectric layer is 261 MPa or more.

5. The actuator according to claim 1, further comprising:
a seed layer provided between the first electrode and the piezoelectric layer, wherein
a lattice constant in an in-plane direction of the piezoelectric layer is smaller than a lattice constant in an in-plane direction of the seed layer.

6. A liquid ejection head, comprising:
the actuator according to claim 1;
a flow path forming substrate formed with a pressure generation chamber having a volume changed by the actuator; and
a nozzle plate provided with a nozzle hole communicating with the pressure generation chamber.

7. A printer comprising:
the liquid ejection head according to claim 6;
a conveyance mechanism configured to move a recording medium with respect to the liquid ejection head; and
a control unit configured to control the liquid ejection head and the conveyance mechanism.
